(19) United States
(12) Patent Application Publication
(10) Pub. No.: US 2024/0120380 A1
(43) Pub. Date: Apr. 11, 2024

(54) FORMING SOURCE/DRAIN REGION IN STACKED FET STRUCTURE

(71) Applicant: INTERNATIONAL BUSINESS MACHINES CORPORATION, ARMONK, NY (US)

(72) Inventors: Chen Zhang, Guilderland, NY (US); Ruilong Xie, Niskayuna, NY (US); Shogo Mochizuki, Mechanicville, NY (US); Tenko Yamashita, Schenectady, NY (US)

(21) Appl. No.: 18/045,181

(22) Filed: Oct. 10, 2022

(51) Int. Cl. H01L 29/08; H01L 21/8234; H01L 27/088; H01L 29/06; H01L 29/423; H01L 29/66; H01L 29/775; H01L 29/786

(52) U.S. Cl. CPC H01L 29/0847; H01L 21/823412; H01L 21/823418; H01L 27/088; H01L 29/0673; H01L 29/42392; H01L 29/66439; H01L 29/775; H01L 29/78696; H01L 29/41733

(57) ABSTRACT

Embodiments of present invention provide a semiconductor structure. The semiconductor structure includes a first nanosheet transistor having a first source/drain (S/D) region; and a second nanosheet transistor on top of the first nanosheet transistor, the second nanosheet transistor having a second S/D region, the second S/D region being separated from the first S/D region by a dielectric cap layer, wherein the first S/D region of the first nanosheet transistor has a substantially flat top surface adjacent to the dielectric cap layer and has at least one vertical edge that is substantially aligned with an edge of the dielectric cap layer. A method of manufacturing the semiconductor structure is also provided.

### BACKGROUND

The present application relates to manufacturing of semiconductor integrated circuits. More particularly, it relates to forming source/drain region in a stacked field-effect-transistor structure and the structure formed thereby.

As semiconductor industry moves towards smaller node, for example 7-nm node and beyond, field-effect-transistors (FETs) are aggressively scaled in order to fit into the reduced footprint or real estate, which is directly associated with the node, with increased device density. Among various types of FETs, non-planar FETs such as nanosheet FETs, and particularly stacked nanosheet FETs, are developed to meet this continued device scaling needs.

A nanosheet FET generally has a channel region that includes one or more elongated semiconductor layers in a stacked configuration, wherein each such semiconductor layer is known as a nanosheet layer (also known as nanosheet channel or simply nanosheet) and has a width that is substantially greater, in general, than a thickness of the nanosheet layer. In a nanosheet FET or nanosheet transistor, gate material is generally formed to surround all sides of each of the stacked nanosheet layers, therefore a nanosheet FET is also sometimes referred to as a gate-all-around (GAA) FET or GAA nanosheet FET. Source and drain of the nanosheet FET are formed at the two ends of the nanosheet layers and access to the source and drain are made through metal contacts formed in, and generally above, the source/drain regions.

In a stacked FET structure, the tight spacing between a top nanosheet transistor and a bottom nanosheet transistor and between two horizontally neighboring nanosheet transistors requires advanced control of the epitaxially growing processes, in both height and width, of the source/drain (S/D) regions of the nanosheet transistors, particularly S/D regions of the bottom nanosheet transistors. For example, when the epitaxial growth of S/D regions of the bottom nanosheet transistor is allowed to grow too tall, it may cause short to the S/D regions of the top nanosheet transistor. Similarly, in the horizontal direction, if the epitaxial growth of S/D regions of the bottom nanosheet transistor is allowed to grow too wide, it may cause short to the source/drain region of an adjacent neighboring nanosheet transistor. The time-based control mechanism used in the currently existing art may not be sufficient enough for such control.

### SUMMARY

Embodiments of present invention provide a semiconductor structure. The semiconductor structure includes a nanosheet transistor with a source/drain (S/D) region, wherein the S/D region has a substantially flat top surface that is adjacent to a dielectric cap layer that is placed directly above the S/D region.

In one embodiment, the S/D region has at least one vertical edge and the at least one vertical edge substantially aligns with an edge of the dielectric cap layer.

In another embodiment, the S/D region has a vertical left edge and a vertical right edge, the vertical left edge and the vertical right edge being substantially aligned with, respectively, a left edge and a right edge of the dielectric cap layer.

In one embodiment, the S/D region is an epitaxially-grown S/D region; and the vertical left edge and the vertical right edge of the S/D region intersect directly with the substantially flat top surface.

In another embodiment, the nanosheet transistor includes one or more nanosheets and wherein the vertical left edge and the vertical right edge of the S/D region are horizontally asymmetric to a horizontal center of the one or more nanosheets.

In one embodiment, the nanosheet transistor is a first nanosheet transistor and the semiconductor structure further includes a second nanosheet transistor positioned vertically above the first nanosheet transistor, wherein a S/D region of the second nanosheet transistor is separated from the S/D region of the first nanosheet transistor by the dielectric cap layer.

In another embodiment, the first nanosheet transistor has a first metal gate and the second nanosheet transistors has a second metal gate, wherein the first metal gate and the second metal gate are connected through a common gate metal.

In yet another embodiment, the S/D region of the first nanosheet transistor and the S/D region of the second nanosheet transistor have different cross-sectional shapes, when looking in a direction along a length of respective gate of the first and the second nanosheet transistor.

Embodiments of present invention also provide a method of forming a semiconductor structure. The method includes forming a first set of nanosheets of a first nanosheet transistor on top of a substrate; covering at least a first end of the first set of nanosheets with a first sacrificial layer; forming a dielectric cap layer above the first sacrificial layer; removing the first sacrificial layer underneath the dielectric cap layer to expose the at least first end of the first set of nanosheets; and epitaxially growing a first S/D region at the at least first end of the first set of nanosheets, wherein at least a portion of the first S/D region underneath the dielectric cap layer is capped by the dielectric cap layer, thereby forming a flat top surface immediately adjacent to the dielectric cap layer.

In one embodiment, the method further includes etching the first S/D region in a reactive-ion-etching (RIE) process using the dielectric cap layer as an etch-mask.

In another embodiment, etching the first S/D region includes causing the first S/D region to have at least one vertical edge that is substantially aligned with the dielectric cap layer.

In yet another embodiment, etching the first S/D region includes causing the first S/D region to have a cross-sectional shape that, when looking in a direction along a length of a gate of the first nanosheet transistor, is horizontally asymmetric relative to a horizontal center of the first set of nanosheets of the first nanosheet transistor.

In one embodiment, forming the dielectric cap layer includes forming a dielectric layer on top of the first sacrificial layer and patterning the dielectric layer into the dielectric cap layer to cover a portion of the first sacrificial layer, the portion of the first sacrificial layer covering at least the first end of the first set of nanosheets of the first nanosheet transistor.

According to one embodiment, the method further includes forming a second set of nanosheets of a second nanosheet transistor above the first set of nanosheets of the first nanosheet transistor and epitaxially growing a second S/D region at a second end of the second set of nanosheets, wherein the second S/D region is separated from the first S/D region at least by the dielectric cap layer.

### BRIEF DESCRIPTION OF THE DRAWINGS

The present invention will be understood and appreciated more fully from the following detailed description of embodiments of present invention, taken in conjunction with accompanying drawings of which:

FIGS. 1A, 1B, and 1C are demonstrative illustrations of cross-sectional views of a semiconductor structure in a step of manufacturing thereof according to one embodiment of present invention;

FIGS. 2A, 2B, and 2C are demonstrative illustrations of cross-sectional views of a semiconductor structure in a step of manufacturing thereof, following the step illustrated in FIGS. 1A, 1B, and 1C, according to one embodiment of present invention;

FIGS. 3A, 3B, and 3C are demonstrative illustrations of cross-sectional views of a semiconductor structure in a step of manufacturing thereof, following the step illustrated in FIGS. 2A, 2B, and 2C, according to one embodiment of present invention;

FIGS. 4A, 4B, and 4C are demonstrative illustrations of cross-sectional views of a semiconductor structure in a step of manufacturing thereof, following the step illustrated in FIGS. 3A, 3B, and 3C, according to one embodiment of present invention;

FIGS. 5A, 5B, and 5C are demonstrative illustrations of cross-sectional views of a semiconductor structure in a step of manufacturing thereof, following the step illustrated in FIGS. 4A, 4B, and 4C, according to one embodiment of present invention;

FIGS. 6A, 6B, and 6C are demonstrative illustrations of cross-sectional views of a semiconductor structure in a step of manufacturing thereof, following the step illustrated in FIGS. 5A, 5B, and 5C, according to one embodiment of present invention;

FIGS. 7A, 7B, and 7C are demonstrative illustrations of cross-sectional views of a semiconductor structure in a step of manufacturing thereof, following the step illustrated in FIGS. 6A, 6B, and 6C, according to one embodiment of present invention;

FIGS. 8A, 8B, and 8C are demonstrative illustrations of cross-sectional views of a semiconductor structure in a step of manufacturing thereof, following the step illustrated in FIGS. 7A, 7B, and 7C, according to one embodiment of present invention;

FIGS. 9A, 9B, and 9C are demonstrative illustrations of cross-sectional views of a semiconductor structure in a step of manufacturing thereof, following the step illustrated in FIGS. 8A, 8B, and 8C, according to one embodiment of present invention;

FIGS. 10A, 10B, and 10C are demonstrative illustrations of cross-sectional views of a semiconductor structure in a step of manufacturing thereof, following the step illustrated in FIGS. 9A, 9B, and 9C, according to one embodiment of present invention;

FIGS. 11A, 11B, and 11C are demonstrative illustrations of cross-sectional views of a semiconductor structure in a step of manufacturing thereof, following the step illustrated in FIGS. 10A, 10B, and 10C, according to one embodiment of present invention;

FIGS. 12A, 12B, and 12C are demonstrative illustrations of cross-sectional views of a semiconductor structure in a step of manufacturing thereof, following the step illustrated in FIGS. 11A, 11B, and 11C, according to one embodiment of present invention;

FIGS. 13A, 13B, and 13C are demonstrative illustrations of cross-sectional views of a semiconductor structure in a step of manufacturing thereof, following the step illustrated in FIGS. 12A, 12B, and 12C, according to one embodiment of present invention;

FIGS. 14A, 14B, and 14C are demonstrative illustrations of cross-sectional views of a semiconductor structure in a step of manufacturing thereof, following the step illustrated in FIGS. 13A, 13B, and 13C, according to one embodiment of present invention;

FIGS. 15A, 15B, and 15C are demonstrative illustrations of cross-sectional views of a semiconductor structure in a step of manufacturing thereof, following the step illustrated in FIGS. 14A, 14B, and 14C, according to one embodiment of present invention; and

FIG. 16 is a demonstrative illustration of a flow-chart of a method of manufacturing a semiconductor structure according to embodiments of present invention.

It will be appreciated that for simplicity and clarity purpose, elements shown in the drawings have not necessarily been drawn to scale. Further, and if applicable, in various functional block diagrams, two connected devices and/or elements may not necessarily be illustrated as being connected. In some other instances, grouping of certain elements in a functional block diagram may be solely for the purpose of description and may not necessarily imply that they are in a single physical entity, or they are embodied in a single physical entity.

### DETAILED DESCRIPTION

In the below detailed description and the accompanying drawings, it is to be understood that various layers, structures, and regions shown in the drawings are both demonstrative and schematic illustrations thereof that are not drawn to scale. In addition, for the ease of explanation, one or more layers, structures, and regions of a type commonly used to form semiconductor devices or structures may not be explicitly shown in a given illustration or drawing. This does not imply that any layers, structures, and regions not explicitly shown are omitted from the actual semiconductor structures. Furthermore, it is to be understood that the embodiments discussed herein are not limited to the particular materials, features, and processing steps shown and described herein. In particular, with respect to semiconductor processing steps, it is to be emphasized that the descriptions provided herein are not intended to encompass all of the processing steps that may be required to form a functional semiconductor integrated circuit device. Rather, certain processing steps that are commonly used in forming semiconductor devices, such as, for example, wet cleaning and annealing steps, are purposefully not described herein for economy of description.

It is to be understood that the terms “about” or “substantially” as used herein with regard to thicknesses, widths, percentages, ranges, etc., are meant to denote being close or approximate to, but not exactly. For example, the term “about” or “substantially” as used herein implies that a small margin of error may be present such as, by way of example only, 1% or less than the stated amount. Likewise, the terms “on”, “over”, or “on top of” that are used herein to describe a positional relationship between two layers or structures are intended to be broadly construed and should not be interpreted as precluding the presence of one or more intervening layers or structures.

To provide spatial context to different structural orientations of the semiconductor structures shown in the drawings, XYZ Cartesian coordinates may be provided in some of the drawings. The terms “vertical” or “vertical direction” or “vertical height” as used herein denote a Z-direction of the Cartesian coordinates shown in the drawings, and the terms “horizontal” or “horizontal direction” or “lateral direction” as used herein denote an X-direction and/or a Y-direction of the Cartesian coordinates shown in the drawings.

Moreover, although various reference numerals may be used across different drawings, the same or similar reference numbers are used throughout the drawings to denote the same or similar features, elements, or structures, and thus detailed explanations of the same or similar features, elements, or structures may not be repeated for each of the drawings for economy of description. Labelling for the same or similar elements in some drawings may be omitted as well in order not to overcrowd the drawings.

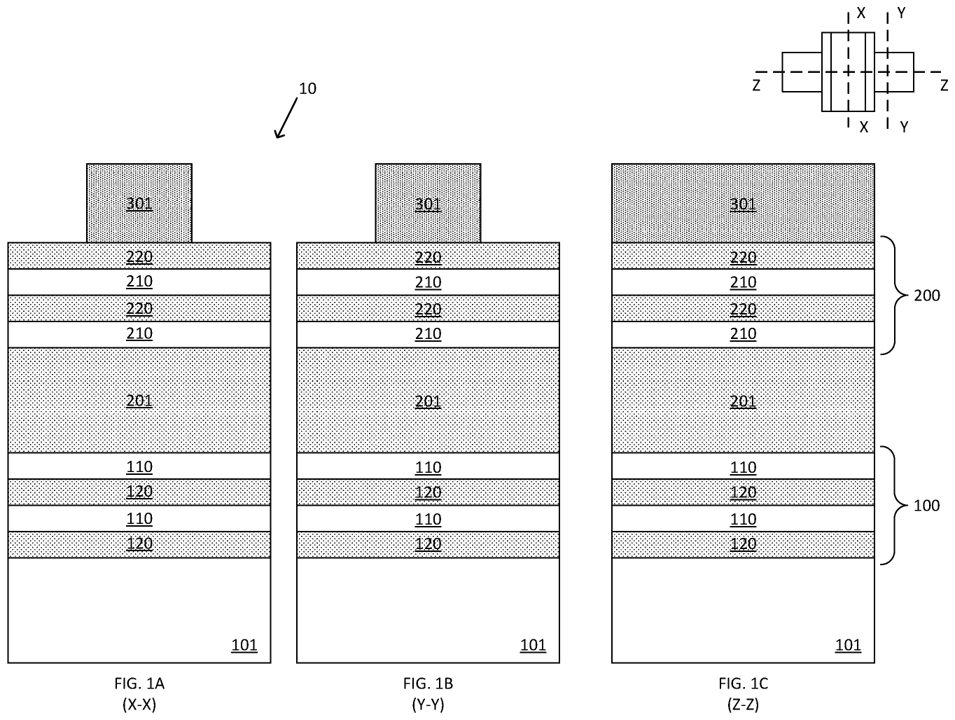

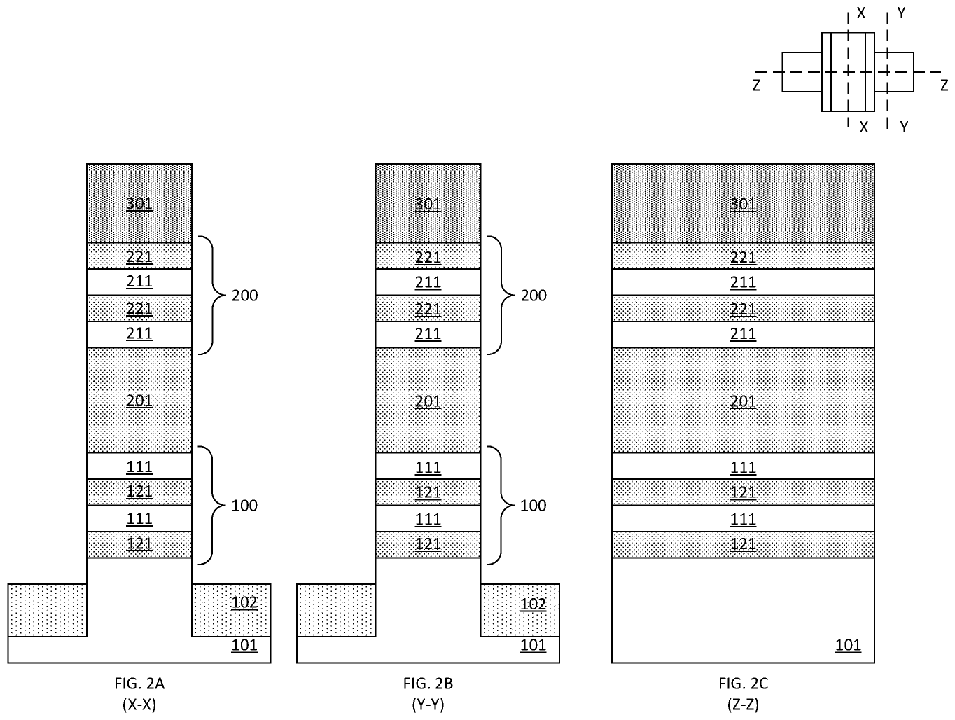

FIGS. 1A, 1B, and 1C are demonstrative illustrations of cross-sectional views of a semiconductor structure in a step of manufacturing thereof according to one embodiment of present invention. More specifically, with reference to a simplified illustration of top view of layout at the upper-right corner, FIG. 1A illustrates a cross-sectional view of a nanosheet transistor structure 10, looking at a direction along a length of the gate from one S/D to another S/D and with the cross-section made along a dashed line X-X at the gate and perpendicular to the nanosheets. FIG. 1B illustrates a cross-sectional view of the nanosheet transistor structure 10, looking at a direction along a length of the gate from one S/D to another S/D and with the cross-section made along a dashed line Y-Y, parallel to the dashed line X-X but off the gate, and perpendicular to the nanosheets. FIG. 1C illustrates a cross-sectional view of the nanosheet transistor structure 10, with the cross-section made along a dashed line Z-Z, parallel to the nanosheets, and across the gate from one S/D to another S/D. Similarly, FIGS. 2A-2C to FIGS. 15A-15C demonstratively illustrate various cross-sectional reviews of the nanosheet transistor structure 10, at various manufacturing stages, in a manner similar to FIGS. 1A-1C.

More particularly, embodiments of present invention provide receiving a supporting structure such as, for example, a semiconductor substrate 101, and forming a first nanosheet transistor 100 and a second nanosheet transistor 200 on top of the semiconductor substrate 101. More specifically, embodiments of present invention provide forming a first stack of blanket nanosheets 110 separated by a first stack of blanket sacrificial sheets 120 for the first nanosheet transistor 100 and a second stack of blanket nanosheets 210 separated by a second stack of blanket sacrificial sheets 220 for the second nanosheet transistor 200. The second stack of blanket nanosheets 210 may be formed on top of the first stack of blanket nanosheets 110 and separated from the first stack of blanket nanosheets 110 by a sacrificial sheet 201. In other words, an uppermost blanket nanosheet 110 of the first stack of blanket nanosheets 110 may be separated from a lowermost blanket nanosheet 210 of the second stack of blanket nanosheets 210 by the sacrificial sheet 201.

With the continuous scaling in the design and manufacturing of semiconductor devices, the sacrificial sheet 201 may be made sufficiently thin to have a thickness ranging from about 10 nm to about 50 nm, or even less, which may pose some serious challenges to the currently existing art in properly forming source/drain regions of the first nanosheet transistor 100 and the second nanosheet transistor 200 without causing some sort of short in-between.

In one embodiment, the first and second stacks of blanket nanosheets 110 and 210 may be silicon (Si) nanosheets or silicon-germanium (SiGe) nanosheets with a first germanium (Ge) concentration level, and the first and second stacks of blanket sacrificial sheets 120 and 220 may be SiGe nanosheets with a second Ge concentration level. The second Ge concentration level of the first and second stacks of blanket sacrificial sheets 120 and 220 may be different from the first Ge concentration level of the first and second stacks of blanket nanosheets 110 and 210 such that the first and second stacks of blanket nanosheets 110 and 210 and the first and second stacks of blanket sacrificial sheets 120 and 220 may have, for example, different etch selectivity to facilitate the formation of the nanosheet transistor structure as being described below in more details. In general, the individual sheet of the first and second stacks of blanket nanosheets 110 and 210 may have a thickness ranging from about 10 nm to about 50, and that of the first and second stacks of blanket sacrificial sheets 120 and 220 may have a thickness ranging from about 5 nm to about 20.

Embodiments of present invention further provide forming a hard mask 301, through a lithographic patterning process, on top of the second stack of blanket nanosheets 210 such as on top of the blanket sacrificial sheet 220 at the top of the stack in preparation for patterning the first and second stacks of blanket nanosheets 110 and 210. In one embodiment, hard mask 301 may include, for example, silicon-nitride (SiN) or other suitable materials.

FIGS. 2A, 2B, and 2C are demonstrative illustrations of cross-sectional views of a semiconductor structure in a step of manufacturing thereof, following the step illustrated in FIGS. 1A, 1B, and 1C according to one embodiment of present invention. More particularly, embodiments of present invention provide patterning the second stack of blanket nanosheets 210 into a second set of blanket nanosheets 211 and the first stack of blanket nanosheets 110 into a first set of blanket nanosheets 111. The patterning may be made through etching by using the hard mask 301 as an etch-mask and may be made in one or more, for example, reactive-ion-etching (RIE) processes. After the patterning, the first set of blanket nanosheets 111 may be separated by a first set of blanket sacrificial sheets 121 and the second set of blanket nanosheets 211 may be separated by a second set of blanket sacrificial sheets 221.

Embodiments of present invention may further include etching the semiconductor substrate 101 to a level below the lowermost blanket sacrificial sheet 121. Next, dielectric material such as, for example, flowable oxide may be formed on top of the remaining semiconductor substrate 101 to form a dielectric layer 102, which surrounds a portion of the semiconductor substrate 101 that is directly underneath the first set of blanket nanosheets 111. The formation of the dielectric layer 102 may leave side surfaces and ends of the first set of blanket nanosheets 111 fully exposed. In other words, the dielectric layer 102 may be formed below the lowermost blanket sacrificial sheet 121. After the formation of the dielectric layer 102, embodiments of present invention provide removing, such as for example through lifting, the hard mask 301 to expose the uppermost blanket sacrificial sheet 221 of the second set of blanket sacrificial sheets 221.

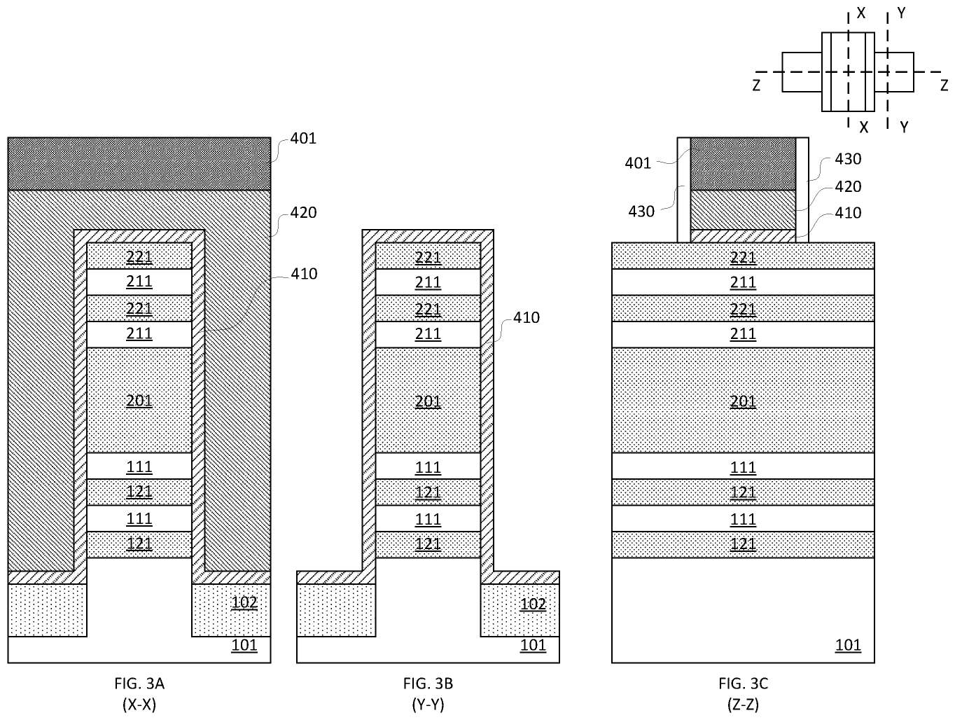

FIGS. 3A, 3B, and 3C are demonstrative illustrations of cross-sectional views of a semiconductor structure in a step of manufacturing thereof, following the step illustrated in FIGS. 2A, 2B, and 2C according to one embodiment of present invention. More particularly, embodiments of present invention provide forming a protective liner 410, such as an EG oxide, covering the first and second sets of blanket nanosheets 111 and 211 and the first and second sets of blanket sacrificial sheets 121 and 221. Embodiments of present invention further provide forming a dummy gate 420 on top of the first and second sets of blanket nanosheets 111 and 211 via the protective liner 410. The dummy gate 420 may be formed through, for example, a lithographic patterning process by first forming a layer of dummy gate material on top of the first and second sets of blanket nanosheets 111 and 211 and then forming a hard mask 401 on top of the layer of dummy gate material. The hard mask 401 may include SiN or other suitable materials. The layer of dummy gate material may subsequently be etched to form the dummy gate 420 using the hard mask 401 as an etch-mask in, for example, an RIE process. Subsequent to the formation of the dummy gate 420, sidewall spacers 430 may be formed at sidewalls of the dummy gate 420 and the hard mask 401.

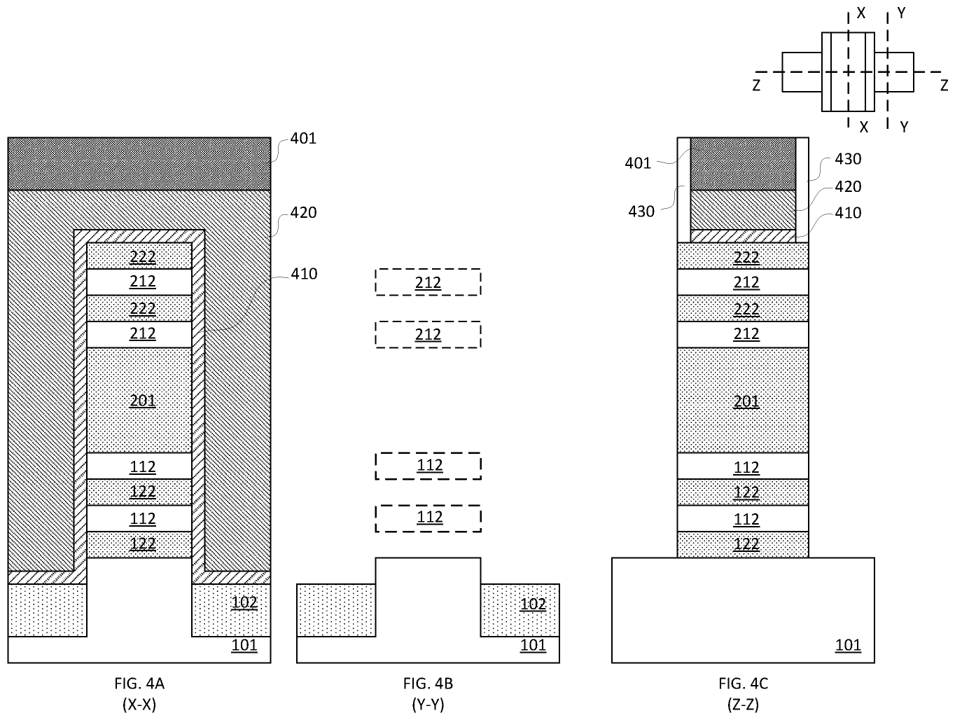

FIGS. 4A, 4B, and 4C are demonstrative illustrations of cross-sectional views of a semiconductor structure in a step of manufacturing thereof, following the step illustrated in FIGS. 3A, 3B, and 3C according to one embodiment of present invention. More particularly, embodiments of present invention provide etching the second set of blanket nanosheets 211 into a second set of nanosheets 212 and etching the first set of blanket nanosheets 111 into a first set of nanosheets 112. The etching process may be performed by using the sidewall spacers 430, the hard mask 401, and the dummy gate 420 as an etch-mask. As a result of the etching process, a first set of sacrificial sheets 122 is formed from the first set of blanket sacrificial sheets 121 that separates the first set of nanosheets 112, and a second set of sacrificial sheets 222 is formed form the second set of blanket sacrificial sheets 221 that separates the second set of nanosheets 212. The first set of nanosheets 112 and the second set of nanosheets 212 are separated by the sacrificial sheet 201.

As is demonstratively illustrated in FIG. 4B, embodiments of present invention provide removing portions of the first and second sets of blanket nanosheets 111 and 211, together with portions of the first and second sets of blanket sacrificial sheets 121 and 221 there in-between, that are not covered by the dummy gate 420. As demonstratively illustrated in FIG. 4C, this removing process creates a first end (e.g., a left-side end) and a second end (e.g., a right-side end) of the first set of nanosheets 112 and a first end (e.g., a left-side end) and a second end (e.g., a right-side end) of the second set of nanosheets 212 respectively. The first and second ends or end surfaces of the first set of nanosheets 112 and the first and second ends or end surfaces of the second set of nanosheets 212 may have cross-sections that are similar to that demonstratively illustrated in FIG. 4A. For the convenience of explanation, the cross-sections of the first and second sets of nanosheets 112 and 212 are illustrated in dashed lines in FIG. 4B to show that the first and second sets of nanosheets 112 and 212 are in the background, at the locations covered by the dummy gate 420 and sidewall spacers 430. On the other hand, FIG. 4B is intended to show that the first and second set of blanket nanosheets 111 and 211 are removed at the location Y-Y.

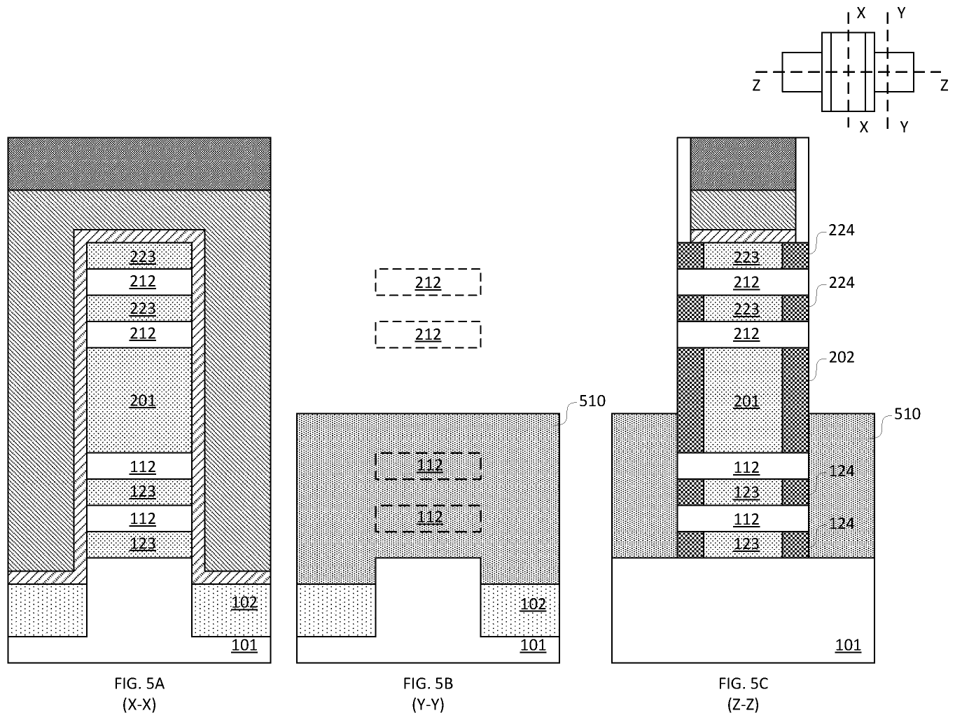

FIGS. 5A, 5B, and 5C are demonstrative illustrations of cross-sectional views of a semiconductor structure in a step of manufacturing thereof, following the step illustrated in FIGS. 4A, 4B, and 4C according to one embodiment of present invention. More particularly, embodiments of present invention provide etching the first set of sacrificial sheets 122 to create a first set of sacrificial sheets 123 and associated indentations at the ends thereof. The indentations are then filled with a dielectric material to form inner spacers 124. Embodiments of present invention also provide etching the second set of sacrificial sheets 222 to create a second set of sacrificial sheets 223 and associated indentations at the ends thereof. The indentations are then filled a dielectric material to form inner spacers 224. Indentations may also be created at the two ends of the sacrificial sheet 201 between the first set of nanosheets 112 and the second set of nanosheets 212 and inner spacers 202 may be formed therein.

Embodiments of present invention may further provide forming a first sacrificial layer 510 such as, for example, a layer of organic planarization layer (OPL), flowable oxide, or other dielectric materials on top of the dielectric layer 102 and the semiconductor substrate 101 and adjacent to the first set of nanosheets 112. The first sacrificial layer 510 may be deposited to a height or vertical level that covers at least end surfaces of the first set of nanosheets 112 without covering end surfaces of the second set of nanosheets 212. In doing so, for example, the first sacrificial layer 510, such as an OPL layer, may be initially deposited to cover both the first set of nanosheets 112 and the second set of nanosheets 212. An etch-back or recessing process may subsequently be applied to the first sacrificial layer 510 such that a top surface of the first sacrificial layer 510 may be lowered to a level above the first set of nanosheets 112 but below the second set of nanosheets 212. That is, the top surface of the first sacrificial layer 510 may be lowered to a position outside the sacrificial sheet 201 and next to the inner spacer 202.

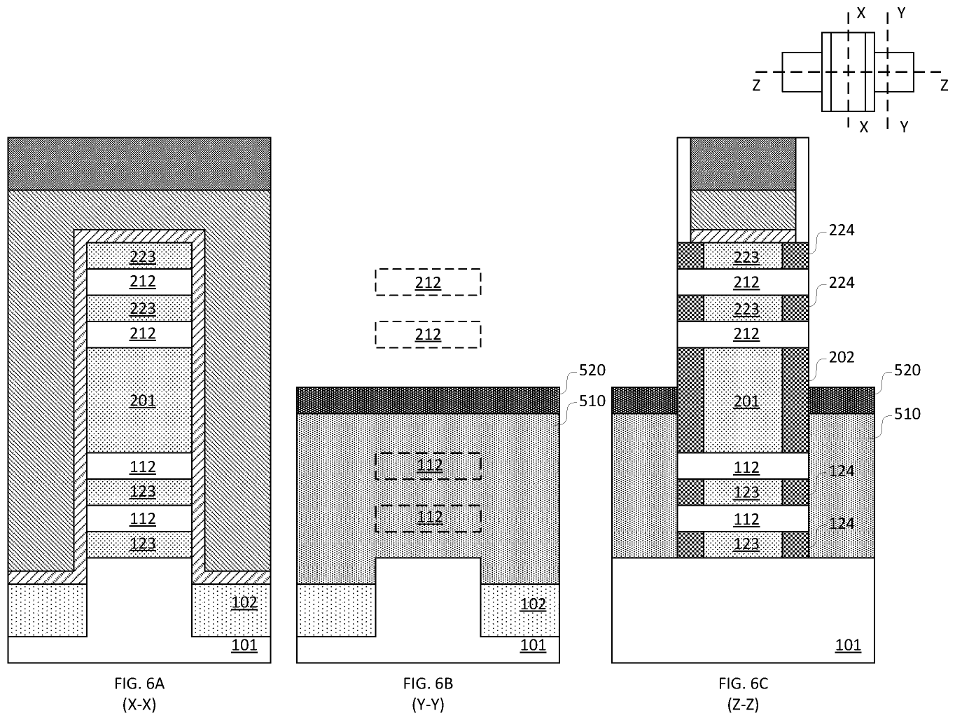

FIGS. 6A, 6B, and 6C are demonstrative illustrations of cross-sectional views of a semiconductor structure in a step of manufacturing thereof, following the step illustrated in FIGS. 5A, 5B, and 5C according to one embodiment of present invention. More particularly, embodiments of present invention provide forming a dielectric layer 520 on top of the first sacrificial layer 510. For example, the dielectric layer 520 may include silicon-nitride (SiN), silicon-oxycarbide (SiCO), silicon-oxycarbonitride (SiOCN), silicoboron-carbonitride (SiBCN) although other suitable materials may be used as well. The dielectric layer 520 may be deposited on top of the first sacrificial layer 510 through, for example, a low-temperature directional deposition process. The dielectric layer 520 may be deposited to a thickness ranging from about 5 nm to about 15 nm. A top surface of the dielectric layer 520 may be below the second set of nanosheets 212 such that end surfaces of the second set of nanosheets 212 are not obscured and remain exposed.

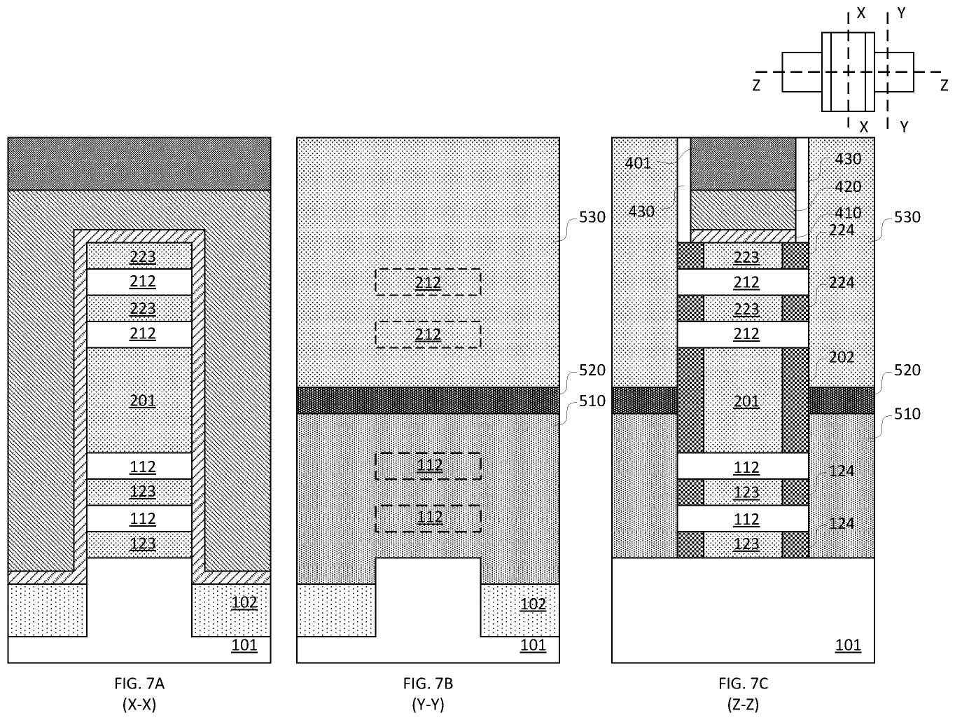

FIGS. 7A, 7B, and 7C are demonstrative illustrations of cross-sectional views of a semiconductor structure in a step of manufacturing thereof, following the step illustrated in FIGS. 6A, 6B, and 6C according to one embodiment of present invention. More particularly, embodiments of present invention provide forming a second sacrificial layer 530 on top of the dielectric layer 520 that covers end surfaces of the second set of nanosheets 212. For example, the second sacrificial layer 530 may be, for example, a flowable-oxide layer and may be formed through a low-temperature deposition process to cover the second set of nanosheets 212 and the dummy gate 420 on top thereof. In one embodiment, a top surface of the second sacrificial layer 530 may be planarized, in preparation for a subsequent patterning process, through a chemical-mechanic-polishing (CMP) process to be planar with the hard mask 401 that is on top of the dummy gate 420.

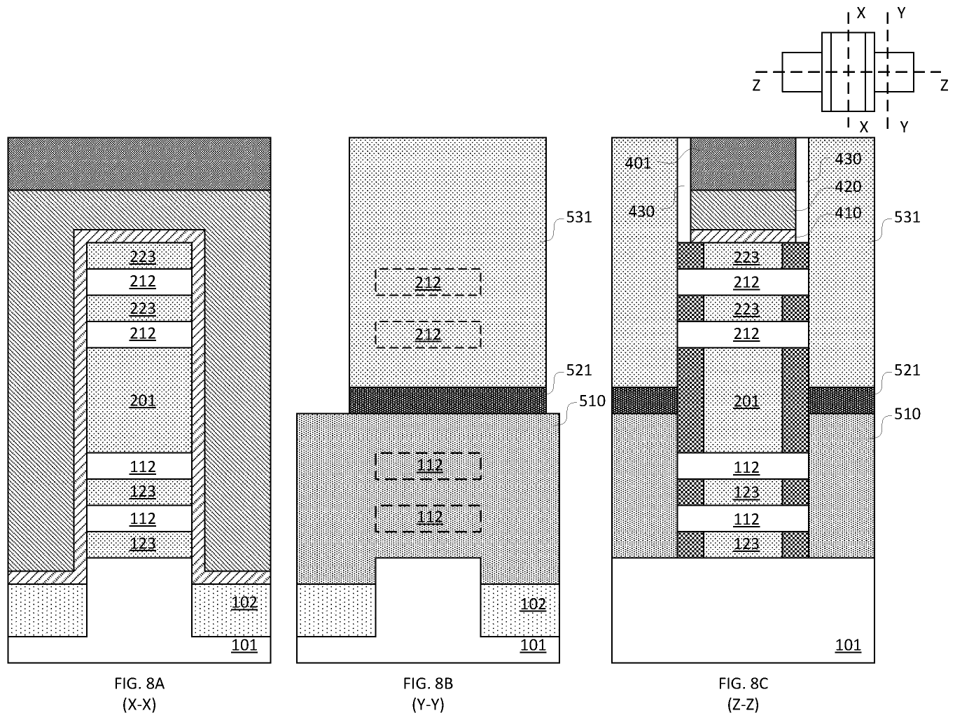

FIGS. 8A, 8B, and 8C are demonstrative illustrations of cross-sectional views of a semiconductor structure in a step of manufacturing thereof, following the step illustrated in FIGS. 7A, 7B, and 7C according to one embodiment of present invention. More particularly, embodiments of present invention provide patterning the second sacrificial layer 530 and the dielectric layer 520, through a lithographic patterning and etching process, to form a modified second sacrificial layer 531 over a dielectric cap layer 521. More specifically, the patterning process may remove a portion of the dielectric layer 520 to expose the underneath first sacrificial layer 510. The remaining portion of the dielectric layer 520 may form the dielectric cap layer 521, covering at least a portion of the first sacrificial layer 510 that covers the end surfaces of the first set of nanosheets 112. The dielectric cap layer 521 may be formed asymmetric to a horizontal center of the first set of nanosheets 112, as is demonstratively illustrated in FIG. 8B, to facilitate for example the formation of source/drain contacts in a downstream manufacturing step of the process. For example, as is demonstratively illustrated in FIG. 8B, the dielectric cap layer 521 may have a bigger portion to the right of the first set of nanosheets 112 and have a smaller portion to the left of the first set of nanosheets 112.

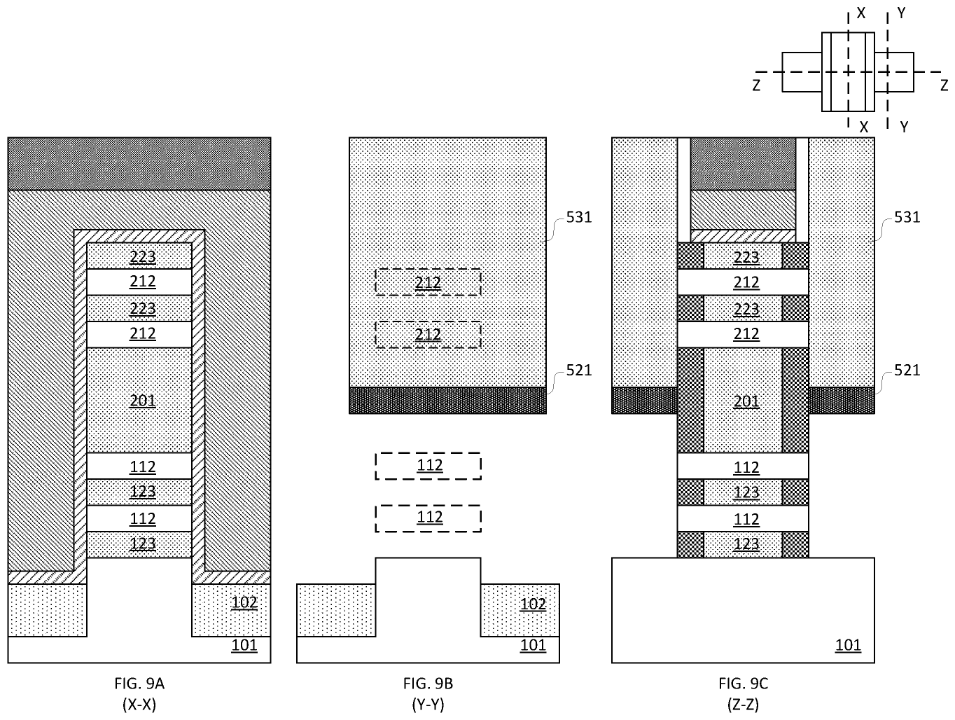

FIGS. 9A, 9B, and 9C are demonstrative illustrations of cross-sectional views of a semiconductor structure in a step of manufacturing thereof, following the step illustrated in FIGS. 8A, 8B, and 8C according to one embodiment of present invention. More particularly, embodiments of present invention provide selectively removing the first sacrificial layer 510 to expose the end surfaces of the first set of nanosheets 112. For example, the first sacrificial layer 510 may be etched away using a selective wet or dry etching process. The removal process may be selective such that it leaves at least the dielectric cap layer 521 substantially un-etched. In one embodiment, the removal process may also leave the modified second sacrificial layer 531 substantially un-etched to remain on top of the dielectric cap layer 521. The modified second sacrificial layer 531 may remain covering the end surfaces of the second set of nanosheets 212 to prevent epitaxial growth at the end surfaces of the second set of nanosheets 212 in a next step that forms S/D regions of the first nanosheet transistor 100.

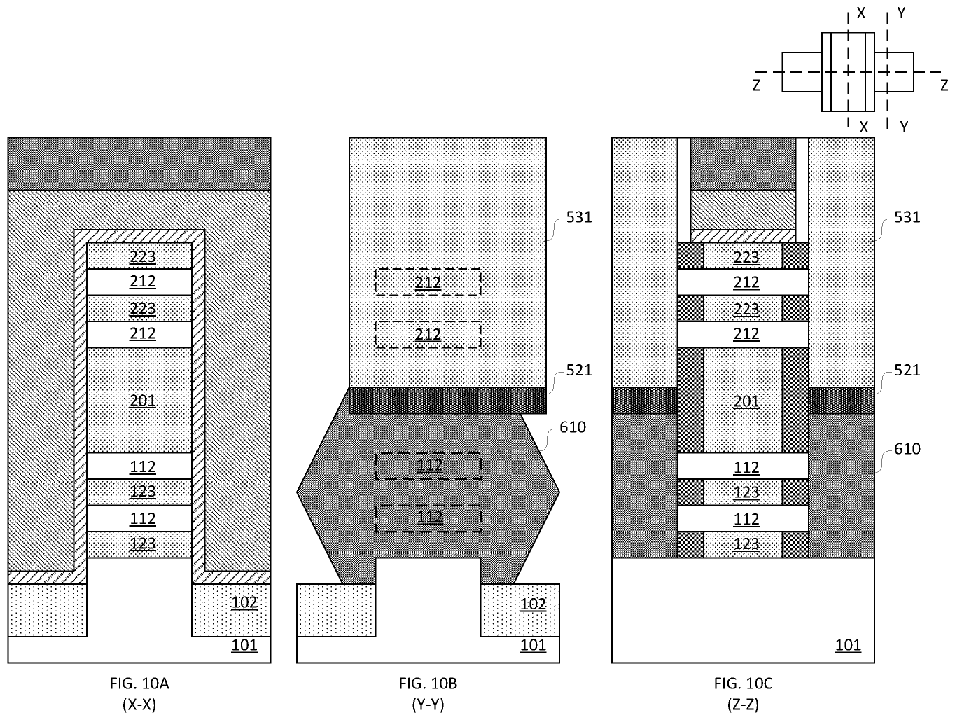

FIGS. 10A, 10B, and 10C are demonstrative illustrations of cross-sectional views of a semiconductor structure in a step of manufacturing thereof, following the step illustrated in FIGS. 9A, 9B, and 9C according to one embodiment of present invention. More particularly, embodiments of present invention provide performing epitaxial growth of an as-grown first S/D region 610 of the first nanosheet transistor 100 at the exposed end surfaces of the first set of nanosheets 112. For example, in one embodiment, the epitaxial growth process may form a symmetric, relative to a horizontal center of the first set of nanosheets 112, as-grown first S/D region 610. The epitaxial growth of the as-grown first S/D region 610 may be at least partially capped at the top by the dielectric cap layer 521, thereby forming a substantially flat top surface of the as-grown first S/D region 610.

In one embodiment, with the epitaxial growth, the as-grown first S/D region 610 may grow to further expand horizontally, at least on one side such as the left side, to the side of the first set of nanosheets 112, as illustrated in FIG. 10B, beyond the left edge of the dielectric cap layer 521. In another embodiment, with the epitaxial growth, the as-grown first S/D region 610 may grow to further expand horizontally at both the left and the right side of the first set of nanosheets 112, as illustrated in FIG. 10B, beyond the left and right edges of the dielectric cap layer 521. In yet another embodiment, the as-grown first S/D region 610 may grow to be fully capped at the top surface by the dielectric cap layer 521 (not shown in FIG. 10B). In other words, the dielectric cap layer 521 may be in full contact with and immediately adjacent to the top surface of the as-grown first S/D region 610.

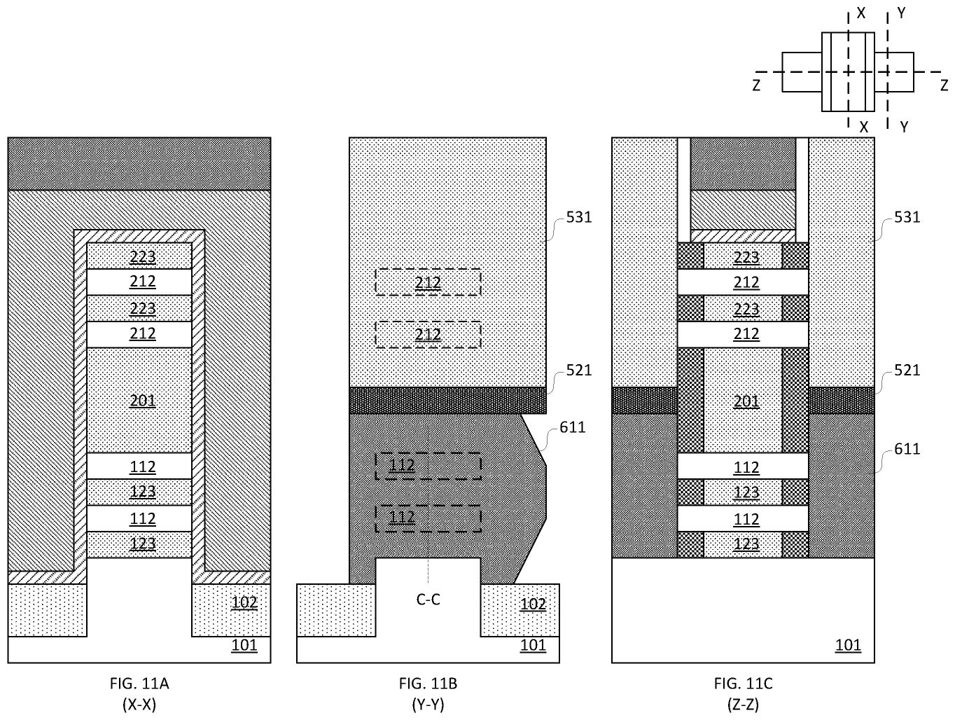

FIGS. 11A, 11B, and 11C are demonstrative illustrations of cross-sectional views of a semiconductor structure in a step of manufacturing thereof, following the step illustrated in FIGS. 10A, 10B, and 10C according to one embodiment of present invention. More particularly, embodiments of present invention provide etching the as-grown first S/D region 610 using the dielectric cap layer 521 as an etch-mask thereby creating a first S/D region 611. In one embodiment, the first S/D region 611 has at least one vertical edge that substantially aligns with an edge of the dielectric cap layer 521. In another embodiment, where both the left and right sides of the as-grown first S/D region 610 are at least partially beyond the left and right edges of the dielectric cap layer 521, the first S/D region 611 may have both a vertical left edge and a vertical right edge. In yet another embodiment, where both the left and right sides of the as-grown first S/D region 610 are fully beyond the left and right edges of the dielectric cap layer 521, the first S/D region 611 may have a vertical left edge and a vertical right edge that are connected by a substantially flat top surface. In other words, the first S/D region 611 may have a vertical left edge and a vertical right edge that intersect with a substantially flat top surface (not shown here).

Moreover, the first S/D region 611 may have a cross-sectional shape when looking in a direction along a length of the gate of the first nanosheet transistor 100 (from one S/D region to another S/D region) as is illustrated in FIG. 11B. The cross-sectional shape may be horizontally asymmetric relative to a horizontal center of the first set of nanosheets 112 of the first nanosheet transistor 100. The horizontal center of the first set of nanosheets 112 is demonstratively illustrated by the dashed line C-C in FIG. 11B.

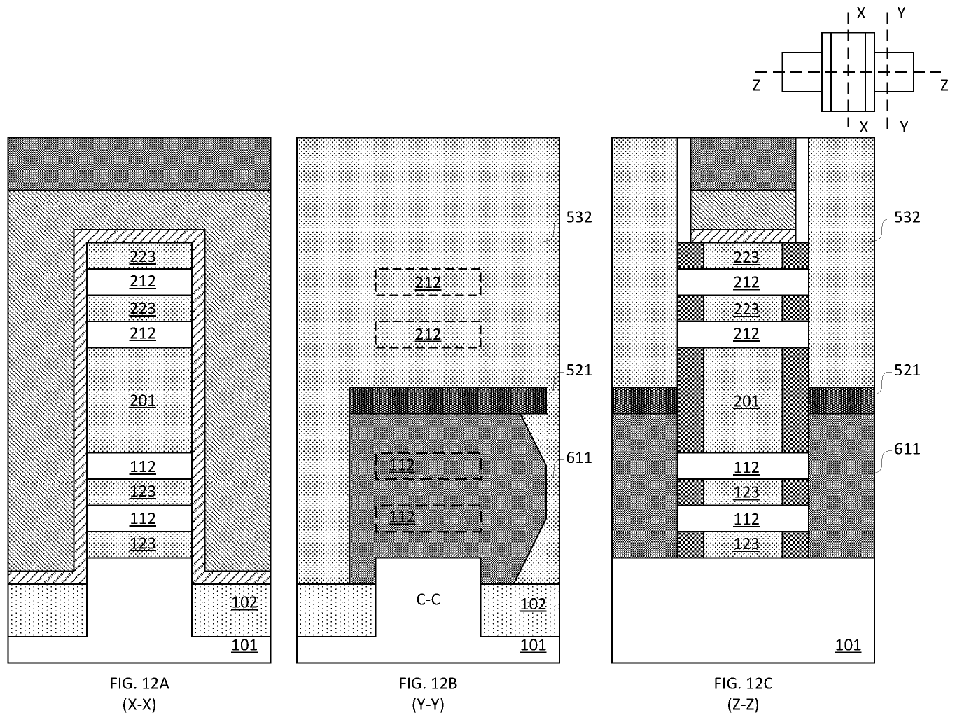

FIGS. 12A, 12B, and 12C are demonstrative illustrations of cross-sectional views of a semiconductor structure in a step of manufacturing thereof, following the step illustrated in FIGS. 11A, 11B, and 11C according to one embodiment of present invention. More particularly, embodiments of present invention provide, after growing and etching to form the first S/D region 611, depositing a dielectric material into spaces surrounding the first S/D region 611. The dielectric material may be the same as, or different from, that of the modified second sacrificial layer 531. Here for the purpose of explanation, FIG. 12B illustrates that deposition of the dielectric material may form a new second sacrificial layer 532 that surrounds the first S/D region 611. The new second sacrificial layer 532 may cover the ends or end surfaces of the second set of nanosheets 212 of the second nanosheet transistor 200.

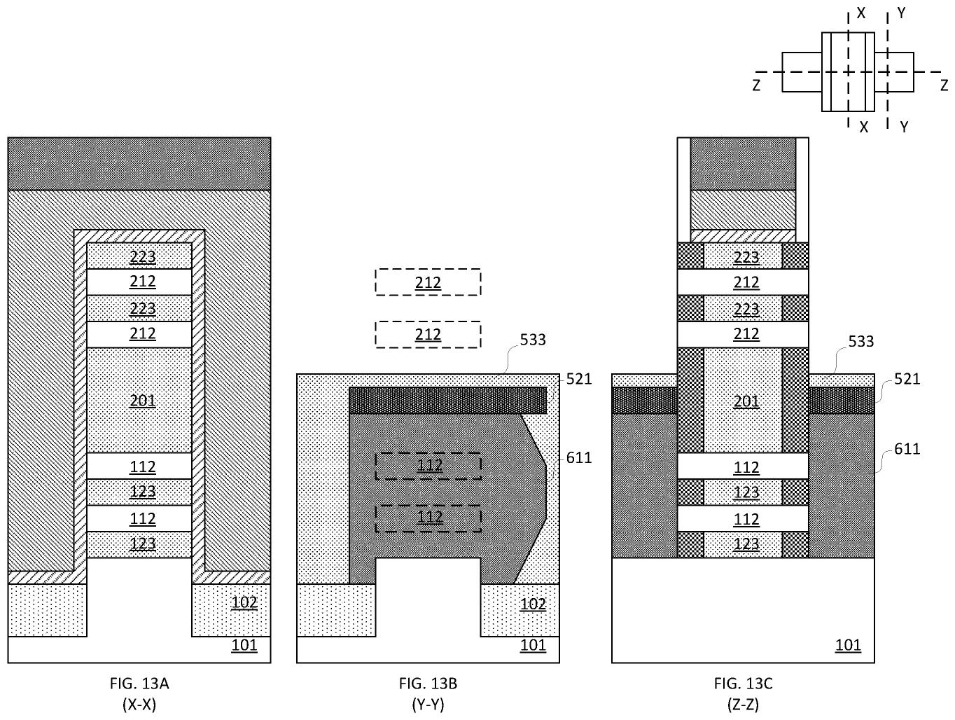

FIGS. 13A, 13B, and 13C are demonstrative illustrations of cross-sectional views of a semiconductor structure in a step of manufacturing thereof, following the step illustrated in FIGS. 12A, 12B, and 12C according to one embodiment of present invention. More particularly, embodiments of present invention provide recessing the new second sacrificial layer 532 to a level below the lowermost nanosheet 212 of the second set of nanosheets 212. In other words, the new second sacrificial layer 532 may be recessed such that end surfaces of the second set of nanosheets 212 may be exposed in preparation for the epitaxial formation of S/D regions of the second nanosheet transistor 200.

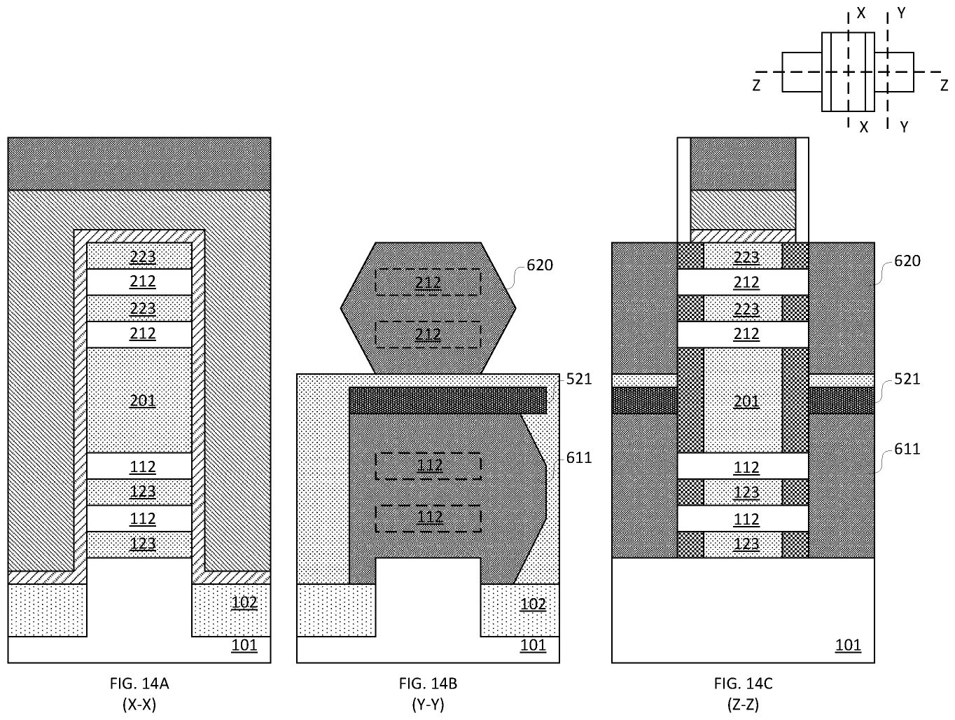

FIGS. 14A, 14B, and 14C are demonstrative illustrations of cross-sectional views of a semiconductor structure in a step of manufacturing thereof, following the step illustrated in FIGS. 13A, 13B, and 13C according to one embodiment of present invention. More particularly, embodiments of present invention provide epitaxially grow a second S/D region 620 at the end surfaces of the second set of nanosheets 212 of the second nanosheet transistor 200. The second S/D region 620 may have a “diamond” shape cross-section, when looking in a direction along a length of the gate from one S/D region to another S/D region. In other words, the cross-sectional shape of the second S/D region 620 of the second nanosheet transistor 200 may be different from that of the first S/D region 611 of the first nanosheet transistor 100. The second S/D region 620 is separated from the first S/D region 611 by the dielectric cap layer 521.

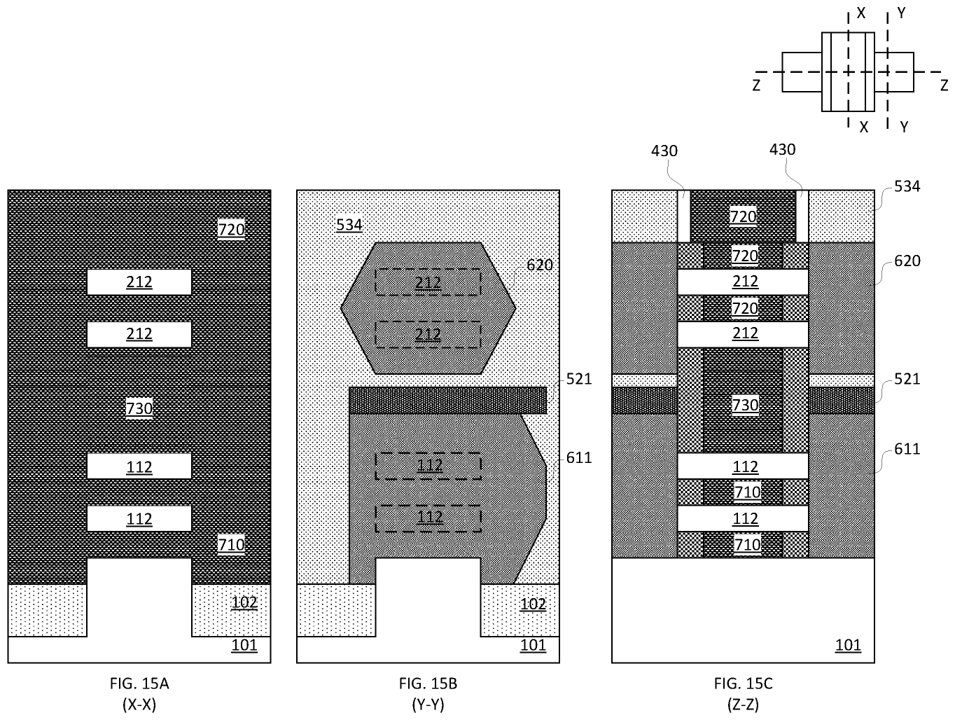

FIGS. 15A, 15B, and 15C are demonstrative illustrations of cross-sectional views of a semiconductor structure in a step of manufacturing thereof, following the step illustrated in FIGS. 14A, 14B, and 14C according to one embodiment of present invention. More particularly, embodiments of present invention provide continuing to finish forming the first and second nanosheet transistors 100 and 200. For example, embodiments of present invention may provide forming a dielectric layer 534 surrounding the second S/D region 620 of the second nanosheet transistor 200 and performing a replacement metal gate (RMG) process to replace the first and second sacrificial sheets 123 and 223 with a first metal gate 710 for the first nanosheet transistor 100 and a second metal gate 720 for the second nanosheet transistor 200. The first and second metal gates 710 and 720 may include a stack of gate metals, including work-function metals. Moreover, the first and second metal gates 710 and 720 may be connected by a common gate metal 730 in-between, that is between the first set of nanosheets 112 and the second set of nanosheets 212.

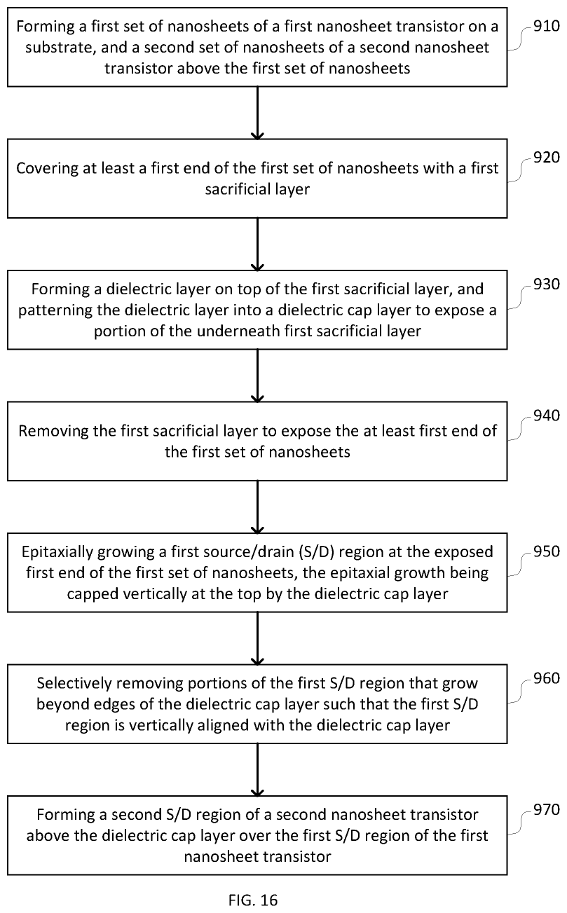

FIG. 16 is a demonstrative illustration of a flow-chart of a method of manufacturing a semiconductor structure according to embodiments of present invention. The method includes (910) forming a first set of nanosheets of a first nanosheet transistor on a substrate and a second set of nanosheets of a second nanosheet transistor above the first set of nanosheets; (920) covering at least a first end of the first set of nanosheets with a first sacrificial layer; (930) forming a dielectric layer on top of the first sacrificial layer and patterning the dielectric layer into a dielectric cap layer corresponding to a portion of the first sacrificial layer that covers the first end of the first set of nanosheets, the patterning exposes a portion of the first sacrificial layer underneath the dielectric layer; (940) removing the first sacrificial layer to expose the at least first end of the first set of nanosheets; (950) epitaxially growing a first S/D region at the exposed first end of the first set of nanosheets, and the epitaxially growing causes the first S/D region to be capped at a top surface by the dielectric cap layer but the first S/D region may grow horizontally partially or fully beyond the edges of the dielectric cap layer; (960) selectively removing, such as through a directional etching, portions of the first S/D region that grow beyond the limits or edges of the dielectric cap layer such that the first S/D region is vertically substantially aligned with the dielectric cap layer; and (970) forming a second S/D region of the second set of nanosheets above the dielectric cap layer, and the second S/D region is separated from the first S/D region by the dielectric cap layer.

It is to be understood that the exemplary methods discussed herein may be readily incorporated with other semiconductor processing flows, semiconductor devices, and integrated circuits with various analog and digital circuitry or mixed-signal circuitry. In particular, integrated circuit dies can be fabricated with various devices such as field-effect transistors, bipolar transistors, metal-oxide-semiconductor transistors, diodes, capacitors, inductors, etc. An integrated circuit in accordance with the present invention can be employed in applications, hardware, and/or electronic systems. Suitable hardware and systems for implementing the invention may include, but are not limited to, personal computers, communication networks, electronic commerce systems, portable communications devices (e.g., cell phones), solid-state media storage devices, functional circuitry, etc. Systems and hardware incorporating such integrated circuits are considered part of the embodiments described herein. Given the teachings of the invention provided herein, one of ordinary skill in the art will be able to contemplate other implementations and applications of the techniques of the invention.

Accordingly, at least portions of one or more of the semiconductor structures described herein may be implemented in integrated circuits. The resulting integrated circuit chips may be distributed by the fabricator in raw wafer form (that is, as a single wafer that has multiple unpackaged chips), as a bare die, or in a packaged form. In the latter case the chip may be mounted in a single chip package (such as a plastic carrier, with leads that are affixed to a motherboard or other high-level carrier) or in a multichip package (such as a ceramic carrier that has surface interconnections and/or buried interconnections). In any case the chip may then be integrated with other chips, discrete circuit elements, and/or other signal processing devices as part of either an intermediate product, such as a motherboard, or an end product. The end product may be any product that includes integrated circuit chips, ranging from toys and other low-end applications to advanced computer products having a display, a keyboard or other input device, and a central processor.

The descriptions of various embodiments of present invention have been presented for the purposes of illustration and they are not intended to be exhaustive and present invention are not limited to the embodiments disclosed. The terminology used herein was chosen to best explain the principles of the embodiments, practical application or technical improvement over technologies found in the marketplace, and to enable others of ordinary skill in the art to understand the embodiments disclosed herein. Many modifications, substitutions, changes, and equivalents will now occur to those of ordinary skill in the art. Such changes, modification, and/or alternative embodiments may be made without departing from the spirit of present invention and are hereby all contemplated and considered within the scope of present invention. It is, therefore, to be understood that the appended claims are intended to cover all such modifications and changes as fall within the spirit of the invention.

What is claimed is:

1. A semiconductor structure comprising:
a nanosheet transistor with a source/drain (S/D) region, wherein the S/D region has a substantially flat top surface that is adjacent to a dielectric cap layer, the dielectric cap layer being placed directly above the S/D region.

2. The semiconductor structure of claim 1, wherein the S/D region has at least one vertical edge and the at least one vertical edge substantially aligns with an edge of the dielectric cap layer.

3. The semiconductor structure of claim 1, wherein the S/D region has a vertical left edge and a vertical right edge, the vertical left edge and the vertical right edge being substantially aligned with, respectively, a left edge and a right edge of the dielectric cap layer.

4. The semiconductor structure of claim 3, wherein the S/D region is formed through an epitaxial growth process, and the vertical left edge and the vertical right edge of the S/D region intersect directly with the substantially flat top surface.

5. The semiconductor structure of claim 4, wherein the nanosheet transistor comprises one or more nanosheets and wherein the vertical left edge and the vertical right edge of the S/D region are horizontally asymmetric to a horizontal center of the one or more nanosheets.

6. The semiconductor structure of claim 1, wherein the nanosheet transistor is a first nanosheet transistor, further comprising a second nanosheet transistor positioned vertically above the first nanosheet transistor, wherein a S/D region of the second nanosheet transistor is separated from the S/D region of the first nanosheet transistor by the dielectric cap layer.

7. The semiconductor structure of claim 6, wherein the first nanosheet transistor has a first metal gate and the second nanosheet transistors has a second metal gate, wherein the first metal gate and the second metal gate are connected through a common gate metal.

8. The semiconductor structure of claim 6, wherein the S/D region of the first nanosheet transistor and the S/D region of the second nanosheet transistor have different cross-sectional shapes when looking in a direction along a length of respective gate of the first and the second nanosheet transistor.

9. A method of forming a semiconductor structure comprising:
forming a first set of nanosheets of a first nanosheet transistor on top of a substrate;
covering at least a first end of the first set of nanosheets with a first sacrificial layer;
forming a dielectric cap layer above the first sacrificial layer;
removing the first sacrificial layer underneath the dielectric cap layer to expose the at least first end of the first set of nanosheets; and
epitaxially growing a first source/drain (S/D) region at the at least first end of the first set of nanosheets,
wherein at least a portion of the first S/D region underneath the dielectric cap layer is capped by the dielectric cap layer, thereby forming a flat substantially top surface adjacent to the dielectric cap layer.

10. The method of claim 9, further comprising etching the first S/D region in a reactive-ion-etching (RIE) process using the dielectric cap layer as an etch-mask to form at least one vertical edge.

11. The method of claim 10, wherein the at least one vertical edge is substantially aligned with the dielectric cap layer.

12. The method of claim 10, wherein etching the first S/D region comprises causing the first S/D region to have a cross-sectional shape that, when looking in a direction along a length of a gate of the first nanosheet transistor, is horizontally asymmetric relative to a horizontal center of the first set of nanosheets of the first nanosheet transistor.

13. The method of claim 9, wherein forming the dielectric cap layer comprises:
forming a dielectric layer on top of the first sacrificial layer; and
patterning the dielectric layer into the dielectric cap layer to cover a portion of the first sacrificial layer,
wherein the portion of the first sacrificial layer covers at least the first end of the first set of nanosheets of the first nanosheet transistor.

14. The method of claim 9, further comprising:
forming a second set of nanosheets of a second nanosheet transistor above the first set of nanosheets of the first nanosheet transistor; and
epitaxially growing a second S/D region at a first end of the second set of nanosheets,
wherein the second S/D region is separated from the first S/D region at least by the dielectric cap layer.

15. A semiconductor structure comprising:
a first nanosheet transistor having a first source/drain (S/D) region; and
a second nanosheet transistor on top of the first nanosheet transistor, the second nanosheet transistor having a second S/D region, the second S/D region being separated from the first S/D region by a dielectric cap layer,
wherein the first S/D region of the first nanosheet transistor has a substantially flat top surface adjacent to the dielectric cap layer and has at least one vertical edge that substantially aligns with an edge of the dielectric cap layer.

16. The semiconductor structure of claim 15, wherein the first S/D region of the first nanosheet transistor and the second S/D region of the second nanosheet transistor have different cross-sectional shapes, when looking in a direction along a length of respective gate of the first nanosheet transistor and the second nanosheet transistor.

17. The semiconductor structure of claim 15, wherein the first S/D region has a vertical left edge and a vertical right edge that are substantially aligned with, respectively, a left edge and a right edge of the dielectric cap layer.

18. The semiconductor structure of claim 17, wherein the vertical left edge and the vertical right edge of the first S/D region are directly connected by the substantially flat top surface of the first S/D region.

19. The semiconductor structure of claim 15, wherein the first nanosheet transistor comprises one or more nanosheets, wherein the first S/D region is horizontally asymmetrical to a horizontal center of the one or more nanosheets.

20. The semiconductor structure of claim 15, wherein the first nanosheet transistor has a first metal gate and second nanosheet transistors has a second metal gate, wherein the first metal gate and the second metal gate are connected through a common gate metal.
